(19) United States
(12) Patent Application Publication
(10) Pub. No.: US 2019/0093224 A1
(43) Pub. Date: Mar. 28, 2019

(54) METHOD OF MANUFACTURING SEMICONDUCTOR DEVICE, SUBSTRATE PROCESSING APPARATUS AND NON-TRANSITORY COMPUTER-READABLE RECORDING MEDIUM

(71) Applicant: KOKUSAI ELECTRIC CORPORATION, Tokyo (JP)

(72) Inventors: Ryosuke YOSHIDA, Toyama-shi (JP); Yukinao KAGA, Toyama-shi (JP); Yuji TAKEBAYASHI, Toyama-shi (JP); Masanori SAKAI, Toyama-shi (JP); Atsushi HIRANO, Toyama-shi (JP)

(73) Assignee: KOKUSAI ELECTRIC CORPORATION, Tokyo (JP)

(21) Appl. No.: 16/136,525

(22) Filed: Sep. 20, 2018

(30) Foreign Application Priority Data
Sep. 25, 2017 (JP) 2017-183602

(51) Int. Cl. C23C 16/455; H01L 21/02

(52) U.S. Cl. CPC C23C 16/45578; C23C 16/45514; H01L 21/02334; C23C 16/45519; C23C 16/45502

(57) ABSTRACT

A technique capable of adjusting a thickness balance of a film between substrates stacked in a process chamber of a substrate processing apparatus, includes a method of manufacturing a semiconductor device, including: (a) supplying source gas to substrates through a first nozzle vertically disposed along a stacking direction of the substrates in a process chamber where the substrates are stacked and accommodated; and (b) supplying reactive gas to the substrates through a second nozzle provided with opening portions and vertically disposed along the stacking direction of the substrates in the process chamber while adjusting a partial pressure balance of the reactive gas in the stacking direction of the substrates to a desired state along the stacking direction of the substrates, wherein an opening area of each of the opening portions increases along a direction from an upstream side to a downstream side of the second nozzle.

### CROSS-REFERENCE TO RELATED PATENT APPLICATION

This non-provisional U.S. patent application claims priority under 35 U.S.C. § 119 of Japanese Patent Application No. 2017-183602, filed on Sep. 25, 2017, in the Japanese Patent Office, the entire contents of which are hereby incorporated by reference.

### BACKGROUND

### 1. Field

The present invention relates to a method of manufacturing a semiconductor device, a substrate processing apparatus and a non-transitory computer-readable recording medium.

### 2. Description of the Related Art

When a film is formed by supplying a gas to a multi-hole nozzle using a vertical type film forming apparatus which is an example of a substrate processing apparatus, a thickness of the film formed on a substrate charged on an upper portion of a boat and a thickness of the film formed on a substrate charged on a lower portion of the boat may be different from each other. Thus, the uniformity (that is, the uniformity of the thickness of the film) between the substrates may deteriorate.

### SUMMARY

Described herein is a technique capable of adjusting a thickness balance of a film between substrates stacked in a process chamber of a substrate processing apparatus.

According to one aspect of the technique described herein, there is provided a method of manufacturing a semiconductor device including: (a) supplying a source gas to substrates through a first nozzle vertically disposed along a stacking direction of the substrates in a process chamber where the substrates are stacked and accommodated; and (b) supplying a reactive gas to the substrates through a second nozzle provided with opening portions and vertically disposed along the stacking direction of the substrates in the process chamber while adjusting a partial pressure balance of the reactive gas to a desired state along the stacking direction of the substrates, wherein an opening area of each of the opening portions increases along a direction from an upstream side to a downstream side of the second nozzle.

### BRIEF DESCRIPTION OF THE DRAWINGS

FIG. 1 schematically illustrates a vertical cross-section of a vertical type process furnace of a substrate processing apparatus according to a first embodiment described herein.

FIG. 2 conceptually illustrates a configuration of gas supply holes 420a of a nozzle 420 of the substrate processing apparatus according to the first embodiment.

FIG. 3 schematically illustrates a cross-section of the vertical type process furnace taken along the line A-A of FIG. 1.

FIG. 4 schematically illustrates a configuration of a controller and components controlled by the controller of the substrate processing apparatus according to the first embodiment.

FIG. 5 is a flowchart illustrating a substrate processing according to the first embodiment.

FIGS. 6A through 6C schematically illustrate flows of gases when a flow rate of NH₃ gas is relatively small. FIG. 6A conceptually illustrates the flows of the gases in the process chamber 201 when the flow rate of the NH₃ gas to the nozzle 420 is relatively small. FIG. 6B conceptually illustrates the flows of the gases in a cross-section taken along the line A-A′ of FIG. 6A. FIG. 6C conceptually illustrates the flows of the gases in a cross-section taken along the line B-B′ of FIG. 6A.

FIGS. 7A through 7C schematically illustrate flows of gases when the flow rate of the NH₃ gas is relatively large. FIG. 7A conceptually illustrates the flows of the gases in the process chamber 201 when the flow rate of the NH₃ gas to the nozzle 420 is relatively large. FIG. 7B conceptually illustrates the flows of the gases in a cross-section taken along the line A-A′ of FIG. 7A. FIG. 7C conceptually illustrates the flows of the gases in a cross-section taken along the line B-B′ of FIG. 7A.

FIG. 8 illustrates a film-forming result of a TiN layer.

FIG. 9 illustrates another film-forming result of the TiN layer.

FIGS. 10A through 10C schematically illustrate flows of gases when a flow rate of N₂ gas is relatively small. FIG. 10A conceptually illustrates the flows of the gases in the process chamber 201 when the flow rate of the N₂ gas to a nozzle 410 is relatively small. FIG. 10B conceptually illustrates the flows of the gases in a cross-section taken along the line A-A′ of FIG. 10A. FIG. 10C conceptually illustrates the flows of the gases in a cross-section taken along the line B-B′ of FIG. 10A.

FIGS. 11A through 11C schematically illustrate flows of gases when the flow rate of the N₂ gas is relatively large. FIG. 11A conceptually illustrates the flows of the gases in the process chamber 201 when the flow rate of the N₂ gas to the nozzle 410 is relatively large. FIG. 11B conceptually illustrates the flows of the gases in a cross-section taken along the line A-A′ of FIG. 11A. FIG. 11C conceptually illustrates the flows of the gases in a cross-section taken along the line B-B′ of FIG. 11A.

### DETAILED DESCRIPTION

### First Embodiment

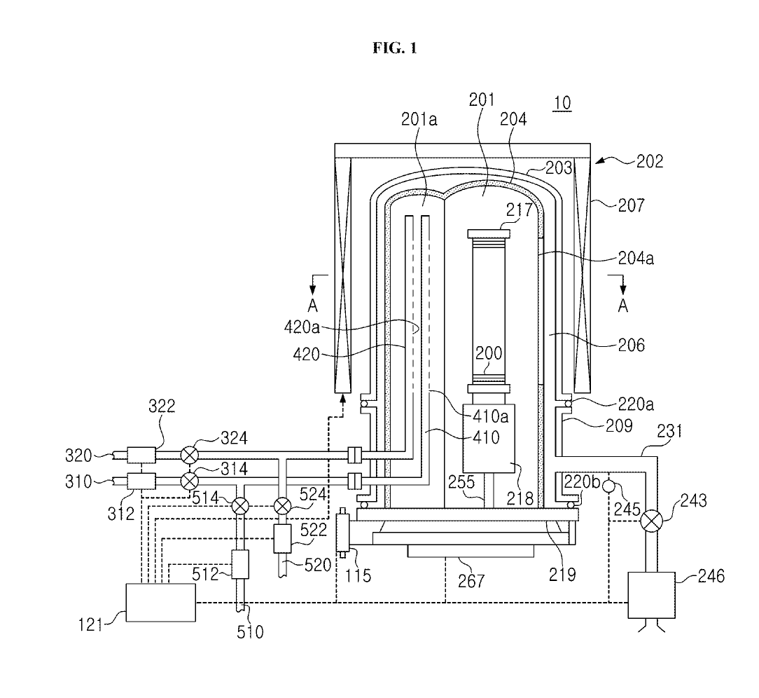

Hereinafter, a first embodiment will be described with reference to FIG. 1 through FIG. 5. A substrate processing apparatus 10 is an example of an apparatus used in a semiconductor device manufacturing process.

(1) Configuration of Substrate Processing Apparatus

The substrate processing apparatus 10 includes a process furnace 202. The process furnace 202 includes a heater 207 serving as a heating device (a heating mechanism or a heating system). The heater 207 is cylindrical and provided in upright manner while being supported by a heater base (not shown) serving as a retaining plate.

An outer tube 203 constituting a reaction vessel (a process vessel) is installed in the heater 207 so as to be concentric with the heater 207. The outer tube 203 is made of a heat resistant material such as quartz (SiO₂) and silicon carbide (SiC). The outer tube 203 is cylindrical with a closed upper end and an open lower end. A manifold 209 (also referred to as an “inlet flange”) is installed under the outer tube 203 so as to be concentric with the outer tube 203. The manifold 209 is made of a metal such as stainless steel (SUS). The manifold 209 is cylindrical with open upper and lower ends. An O-ring 220a serving as a sealing member is installed between the upper end of the manifold 209 and the outer tube 203. The outer tube 203 is provided in upright manner while supported by the manifold 209 supported by the heater base.

An inner tube 204 constituting the reaction vessel is installed in the outer tube 203. The inner tube 204 is made of a heat resistant material such as quartz (SiO₂) and silicon carbide (SiC). The inner tube 204 is cylindrical with a closed upper end and an open lower end. The process vessel (the reaction vessel) is constituted by the outer tube 203, the inner tube 204 and the manifold 209. A process chamber 201 is provided in the hollow cylindrical portion (the inside of the inner tube 204) of the process vessel.

The process chamber 201 is configured to accommodate vertically arranged wafers 200 serving as substrates in a horizontal orientation in a multistage manner by a boat 217 to be described later. A nozzle 410 serving as a first nozzle and a nozzle 420 serving as a second nozzle are installed in the process chamber 201 to penetrate a sidewall of the manifold 209 and the inner tube 204. Gas supply pipes 310 and 320 serving as gas supply lines are connected to the nozzles 410 and 420, respectively. As described above, the substrate processing apparatus 10 includes the two nozzles 410 and 420 and the two gas supply pipes 310 and 320. Different gases may be supplied into the process chamber 201 via the two nozzles 410 and 420 and the two gas supply pipes 310 and 320. However, the process furnace 202 according to the first embodiment is not limited thereto.

MFCs (Mass Flow Controllers) 312 and 322 serving as flow rate controllers (flow rate control mechanisms) and valves 314 and 324 serving as opening/closing valves are sequentially installed at the gas supply pipes 310 and 320, respectively, from the upstream side to the downstream side of the gas supply pipes 310 and 320. Gas supply pipes 510 and 520 configured to supply an inert gas are connected to the gas supply pipes 310 and 320 at the downstream sides of the valves 314 and 324, respectively. MFCs 512 and 522 and valves 514 and 524 are sequentially installed at the gas supply pipes 510 and 520, respectively, from the upstream side to the downstream side of the gas supply pipes 510 and 520.

The nozzles 410 and 420 are connected to front ends of the gas supply pipes 310 and 320, respectively. The nozzles 410 and 420 may include L-shaped nozzles. Horizontal portions of the nozzles 410 and 420 are installed through the sidewall of the manifold 209 and the inner tube 204. Vertical portions of the nozzles 410 and 420 protrude outward from the inner tube 204 and are installed in a preliminary chamber 201a having a channel shape (a groove shape) extending in the vertical direction. That is, the vertical portions of the nozzles 410 and 420 are installed in the preliminary chamber 201a toward the top of the inner tube 204 (in the direction in which the wafers 200 are stacked) and along an inner wall of the inner tube 204.

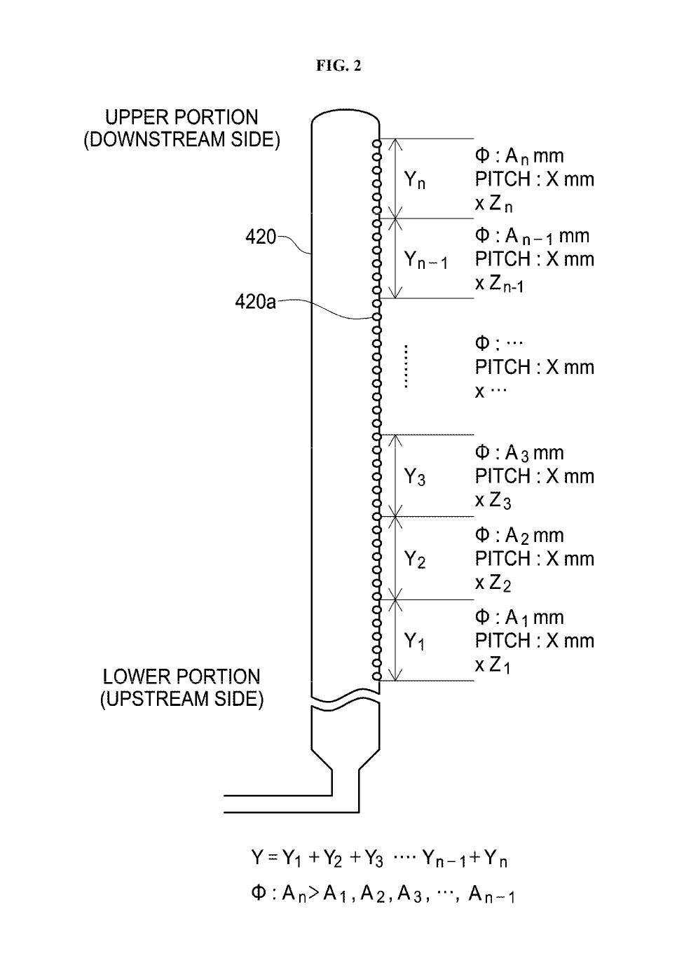

The nozzles 410 and 420 extend from a lower region of the process chamber 201 to an upper region of the process chamber 201. The nozzles 410 and 420 are provided with gas supply holes 410a and 420a facing the wafers 200, respectively, such that the process gases are supplied to the wafers 200 through the gas supply holes 410a and 420a of the nozzles 410 and 420. The gas supply holes 410a are also referred to opening portions of the nozzles 410, and the gas supply holes 420a are also referred to opening portions of the nozzles 420. The gas supply holes 410a are provided so as to correspond to a lower region to an upper region of the inner tube 204, and have the same opening area and the same pitch. However, the gas supply holes 410a are not limited thereto. The opening areas of the gas supply holes 410a may gradually increase along a direction from the lower region toward the upper region of the inner tube 204 to maintain the uniformity of the amounts of the gases supplied through the gas supply holes 410a. The gas supply holes 420a of the nozzle 420 will be described in detail below with reference to FIG. 2.

The gas supply holes 420a of the nozzle 420 are provided at positions facing the wafers 200 so as to correspond to a lower portion (that is, an upstream side) to an upper portion (that is, a downstream side) of the nozzle 420. Among the gas supply holes 420a in the nozzle 420, the hole diameter ϕ (opening area) of a gas supply hole 420a in the lower portion (upstream side) of the nozzle 420 is smaller than that of a gas supply hole 420a in the upper portion (downstream side) of the nozzle 420. That is, the hole diameter ϕ of each of the gas supply holes 420a in the nozzle 420 increases along a direction from the upstream side to the downstream side of the nozzle 420. In other words, the opening area of each of the gas supply holes 420a in the nozzle 420 increases along a direction from the upstream side to the downstream side of the nozzle 420.

In the description above, “the lower portion (upstream side) of the nozzle 420” refers to a lower side of the nozzle 420 which is provided in the process chamber 201 and vertically extends along a stacking direction of the wafers 200, that is, the side in which a supply source of a reactive gas is located or the upstream side of the flow of the reactive gas in the nozzle 420. Similarly, “the upper portion (downstream side) of the nozzle 420” refers to an upper side of the nozzle 420 which is provided in the process chamber 201 and vertically extends along the stacking direction of the wafers 200, that is, the downstream side of the flow of the reactive gas in the nozzle 420.

Let Y be a region where the gas supply holes 420a of the nozzle 420 are located. Then, the region Y can be divided into regions, which are a first region Y₁, a second region Y₂, a third region Y₃, . . . , an (n−1)^{th} region Yₙ₋₁ and an n^{th} region Yₙ, from the lower portion (upstream side) to the upper portion (downstream side) of the nozzle 420. Z₁ number of gas supply holes 420a with hole diameter ϕ of A₁ mm and pitch of X mm are located in the first region Y₁. Z₂ number of gas supply holes 420a with hole diameter ϕ of A₂ mm and pitch of X mm are located in the second region Y₂. Z₃ number of gas supply holes 420a with hole diameter ϕ of A₃ mm and pitch of X mm are located in the third region Y₃. Similarly, Zₙ₋₁ number of gas supply holes 420a with hole diameter ϕ of Aₙ₋₁ mm and pitch of X mm are located in the (n−1)^{th} region Yₙ₋₁. Zₙ number of gas supply holes 420a with hole diameter ϕ of Aₙ mm and pitch of X mm are located in the n^{th} region Yₙ. In the above description, X and A₁ through Aₙ are real numbers greater than 0, and Z₁ through Zₙ are natural numbers. Z₁ through Zₙ may be the same or different from one another.

The relation of the hole diameters ϕ of the gas supply holes 420a in each regions Y₁ through Yₙ can be represented as follows:

ϕ: Aₙ>A₁, A₂, A₃, . . . , Aₙ₋₁

That is, the hole diameter Aₙ of the gas supply holes 420a of the n^{th} region Yₙ is greater than each of the hole diameters A₁ through Aₙ₋₁ of the gas supply holes 420a of the other regions which are the first region Y₁ through the (n−1)^{th} region Yₙ₋₁. For example, when an absolute value of the hole diameter ϕ may range from 0.5 mm to 3.0 mm, a relative ratio of A₁ to Aₙ may range from 1:1.01 to 1:6.

With the above configurations of the gas supply holes 420a, by adjusting the flow rate of the process gas supplied into the process chamber 201 through the gas supply holes 420a of the nozzle 420, it is possible to adjust a partial pressure balance of the process gas in the process chamber 201 to a desired state of the partial pressure balance. In this embodiment, a distribution of the partial pressure in the stacking direction of the wafers 200 is mainly referred as the partial pressure balance in the process chamber 201.

The gas supply holes 410a and 420a of the nozzles 410 and 420 are provided to correspond to a lower portion to an upper portion of the boat 217 to be described later. Therefore, the process gases supplied into the process chamber 201 through the gas supply holes 410a and 420a of the nozzles 410 and 420 are supplied onto the wafers 200 accommodated in the boat 217 from the lower portion to the upper portion thereof, that is, the entirety of the wafers 200 accommodated in the boat 217. The nozzles 410 and 420 extend from the lower region to the upper region of the process chamber 201. However, the nozzles 410 and 420 may extend only to the vicinity of the ceiling of the boat 217.

A source gas containing a first metal element (also referred to as a first metal-containing gas or a first source gas), which is one of the process gases, is supplied to the process chamber 201 through the gas supply pipe 310 provided with the MFC 312 and the valve 314 and the nozzle 410. For example, titanium tetrachloride (TiCl₄), which contains titanium (Ti) as the first metal element and serves as a halogen-based source (also referred to as a halide or halogen-based titanium source), may be used as a source of the source gas.

A reactive gas, which is one of the process gases, is supplied to the process chamber 201 through the gas supply pipe 320 provided with the MFC 322 and the valve 324 and the nozzle 420. For example, a nitrogen (N)-containing gas such as ammonia (NH₃) gas may be used as the reactive gas. NH₃ acts as a nitriding and reducing agent (a nitriding and reducing gas).

The inert gas, such as nitrogen (N₂) gas, is supplied into the process chamber 201 via the gas supply pipes 510 and 520 provided with the MFCs 512 and 522 and the valves 514 and 524, and the nozzles 410 and 420, respectively. While the N₂ gas is exemplified as the inert gas in the first embodiment, rare gases such as argon (Ar) gas, a helium (He) gas, neon (Ne) gas and xenon (Xe) gas may be used as the inert gas instead of the N₂ gas.

While a process gas supply system may be constituted by the gas supply pipes 310 and 320, the MFCs 312 and 322, the valves 314 and 324, and the nozzles 410 and 420, only the nozzles 410 and 420 may be considered as the process gas supply system. The process gas supply system may be simply referred to as a gas supply system. When the source gas is supplied through the gas supply pipe 310, a source gas supply system is constituted by the gas supply gas supply pipe 310, the MFC 312 and the valve 314. The source gas supply system may further include the nozzle 410. The source gas supply system may be simply referred to as a source supply system. When a metal-containing gas such as the first metal-containing gas is used as the source gas, the source gas supply system may also be referred to as a metal-containing source gas supply system. When the reactive gas is supplied through the gas supply pipe 320, a reactive gas supply system is constituted by the gas supply pipe 320, the MFC 322 and the valve 324. The reactive gas supply system may further include the nozzle 420. When the nitrogen-containing gas serving as the reactive gas is supplied through the gas supply pipe 320, the reactive gas supply system may be referred to as a nitrogen-containing gas supply system. An inert gas supply system is constituted by the gas supply pipes 510 and 520, the MFCs 512 and 522, and the valves 514 and 524. The inert gas supply system may also be referred to as a purge gas supply system, a dilution gas supply system, or a carrier gas supply system.

According to the first embodiment, a gas is supplied into the vertically long annular space which is defined by the inner wall of the inner tube 204 and the edges (peripheries) of the wafers 200 through the nozzles 410 and 420 provided in the preliminary chamber 201a. The gas is injected into the inner tube 204 around the wafers 200 through the gas supply holes 410a and 420a provided at the nozzles 410 and 420 and facing the wafer 200, respectively. Specifically, the gas such as the source gas is injected into the inner tube 204 in the horizontal direction, that is, in a direction parallel to the surfaces of the wafers 200 through the gas supply holes 410a and 420a of the nozzles 410 and 420, respectively.

An exhaust hole (exhaust port) 204a having a narrow slit-shape elongating vertically and facing the nozzles 410 and 420, is provided in the sidewall of the inner tube 204 opposite to the preliminary chamber 201a. The gas supplied into the process chamber 201 through the gas supply holes 410a and 420a of the nozzles 410 and 420 flows through the surfaces of the wafers 200, and then exhausted through the exhaust hole 204a into an exhaust channel 206 which is a gap between the inner tube 204 and the outer tube 203. The gas flowing in the exhaust channel 206 flows into an exhaust pipe 231 and is then discharged out of the process furnace 202.

The exhaust hole 204a is provided to face the wafers 200 (preferably, to correspond to the upper portion and the lower portion of the boat 217). A gas supplied in the vicinity of the wafers 200 in the process chamber 201 through the gas supply holes 410a and 420a flows in the horizontal direction, that is, a direction parallel to the surfaces of the wafers 200, and then exhausted through the exhaust hole 204a into the exhaust channel 206. That is, the gas remaining in the process chamber 201 is exhausted in parallel to the surfaces of the wafers 200 through the exhaust hole 204a. Furthermore, the exhaust hole 204a is not limited to a slit-shaped through-hole and may include a plurality of holes.

The exhaust pipe 231 for exhausting an inner atmosphere of the process chamber 201 is provided at the manifold 209. A vacuum pump 246 serving as a vacuum exhaust apparatus, a pressure sensor 245 serving as a pressure detector (pressure detection mechanism) to detect an inner pressure of the process chamber 201, and an APC (Automatic Pressure Controller) valve 243 serving as a pressure controller (pressure control mechanism) are connected to the exhaust pipe 231 from the upstream side to the downstream side of the exhaust pipe 231. With the vacuum pump 246 in operation, the APC valve 243 may be opened/closed to vacuum-exhaust the process chamber 201 or stop the vacuum exhaust. With the vacuum pump 246 in operation, the opening degree of the APC valve 243 may be adjusted in order to control the inner pressure of the process chamber 201. An exhaust system (an exhaust line) is constituted by the exhaust hole 204a, the exhaust channel 206, the exhaust pipe 231, the APC valve 243 and the pressure sensor 245. The exhaust system may further include the vacuum pump 246.

A seal cap 219, serving as a furnace opening cover capable of sealing a lower end opening of the manifold 209 in airtight manner, is provided under the manifold 209. The seal cap 219 is in contact with the lower end of the manifold 209 from thereunder. The seal cap 219 is made of metal such as SUS, and is disk-shaped. The O-ring 220b, serving as a sealing member and being in contact with the lower end of the manifold 209, is provided on an upper surface of the seal cap 219. A rotating mechanism 267 configured to rotate the boat 217 to be described later is provided in the seal cap 219 opposite to the process chamber 201. A rotating shaft 255 of the rotating mechanism 267 is connected to the boat 217 through the seal cap 219. As the rotating mechanism 267 rotates the boat 217, the wafers 200 are rotated. The seal cap 219 may be moved upward/downward in the vertical direction by a boat elevator 115 installed outside the outer tube 203 vertically and serving as an elevating mechanism. When the seal cap 219 is moved upward/downward by the boat elevator 115, the boat 217 may be loaded into the process chamber 201 or unloaded out of the process chamber 201. The boat elevator 115 serves as a transfer device (transfer mechanism) that loads the boat 217 and the wafers 200 accommodated in the boat 217 into the process chamber 201 or unloads the boat 217 and the wafers 200 accommodated in the boat 217 out of the process chamber 201.

The boat 217 serving as a substrate retainer supports the wafers 200 (for example, 25 to 200 wafers), which are concentrically arranged in the vertical direction and in horizontally orientation. The wafers 200 are arranged with a gap therebetween. The boat 217 is made of a heat resistant material such as quartz and SiC. An insulating plate 218 is installed in multi-stages under the boat 217. The insulating plate 218 is made of a heat resistant material such as quartz and SiC. The insulating plate 218 suppresses the heat transfer from the heater 207 to the seal cap 219. However, the first embodiment is not limited thereto. For example, instead of the insulating plate 218, a heat insulating cylinder (not shown) may be installed as a cylindrical member made of a heat resistant material such as quartz and SiC.

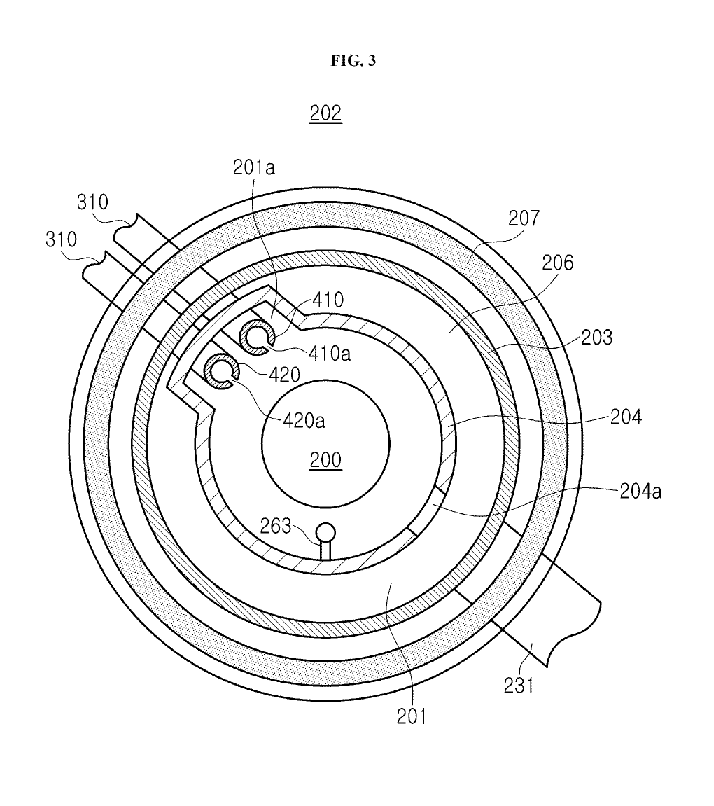

As shown in FIG. 3, a temperature sensor 263 serving as a temperature detector is installed in the inner tube 204. The energization state of the heater 207 is adjusted based on the temperature detected by the temperature sensor 263 such that an inner temperature of the process chamber 201 has a desired temperature distribution. The temperature sensor 263 is L-shaped like the nozzles 410 and 420, and provided along the inner wall of the inner tube 204.

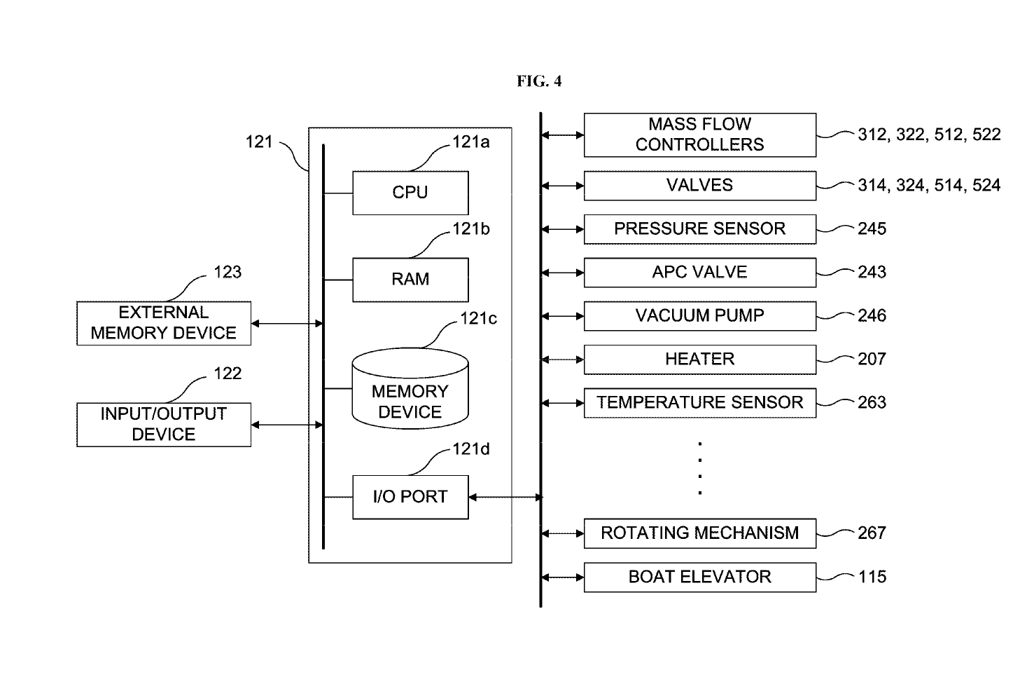

As shown in FIG. 4, the controller 121 serving as a control device (control mechanism) is embodied by a computer including a CPU (Central Processing Unit) 121a, a RAM (Random Access Memory) 121b, a memory device 121c and an I/O port 121d. The RAM 121b, the memory device 121c and the I/O port 121d may exchange data with the CPU 121a through an internal bus. For example, an input/output device 122 such as a touch panel is connected to the controller 121.

The memory device 121c is embodied by components such as a flash memory and a HDD (Hard Disk Drive). A control program for controlling the operation of the substrate processing apparatus 10 or a process recipe containing information on the sequences and conditions of a substrate processing (that is, a method of manufacturing a semiconductor device) described later is readably stored in the memory device 121c. The process recipe is obtained by combining steps of the substrate processing described later such that the controller 121 can execute the steps to acquire a predetermine result, and functions as a program. Hereafter, the process recipe and the control program are collectively referred to as a program. In the present specification, the term “program” may indicate only the process recipe, indicate only the control program, or indicate both of them. The RAM 121b is a work area where a program or data read by the CPU 121a is temporarily stored.

The I/O port 121d is connected to the above-described components such as the MFCs 312, 322, 512 and 522, the valves 314, 324, 514 and 524, the pressure sensor 245, the APC valve 243, the vacuum pump 246, the heater 207, the temperature sensor 263, the rotating mechanism 267 and the boat elevator 115.

The CPU 121a is configured to read a control program from the memory device 121c and execute the read control program. Furthermore, the CPU 121a is configured to read a process recipe from the memory device 121c according to an operation command inputted from the input/output device 122. According to the contents of the read process recipe, the CPU 121a may be configured to control various operations such as flow rate adjusting operations for various gases by the MFCs 312, 322, 512 and 522, opening/closing operations of the valves 314, 324, 514 and 524, an opening/closing operation of the APC valve 243, a pressure adjusting operation by the APC valve 243 based on the pressure sensor 245, a temperature adjusting operation of the heater 207 based on the temperature sensor 263, a start and stop of the vacuum pump 246, a rotation and rotation speed adjusting operation of the boat 217 by the rotating mechanism 267, an elevating and lowering operation of the boat 217 by the boat elevator 115, and a transfer operation of the wafers 200 into the boat 217.

The controller 121 may be embodied by installing the above-described program stored in an external memory device 123 into a computer, the external memory device 123 including, for example, a magnetic tape, a magnetic disk such as a flexible disk and a hard disk, an optical disk such as a CD and a DVD, a magneto-optical disk such as an MO, and a semiconductor memory such as a USB memory and a memory card. The memory device 121c or the external memory device 123 may be embodied by a computer-readable recording medium. Hereafter, the memory device 121c and the external memory device 123 are collectively referred to as recording media. In the present specification, “recording media” may indicate only the memory device 121c, indicate only the external memory device 123, and indicate both of the memory device 121c and the external memory device 123. Instead of the external memory device 123, a communication means such as the Internet and a dedicated line may be used for providing the program to the computer.

(2) Substrate Processing (Film-Forming Steps)

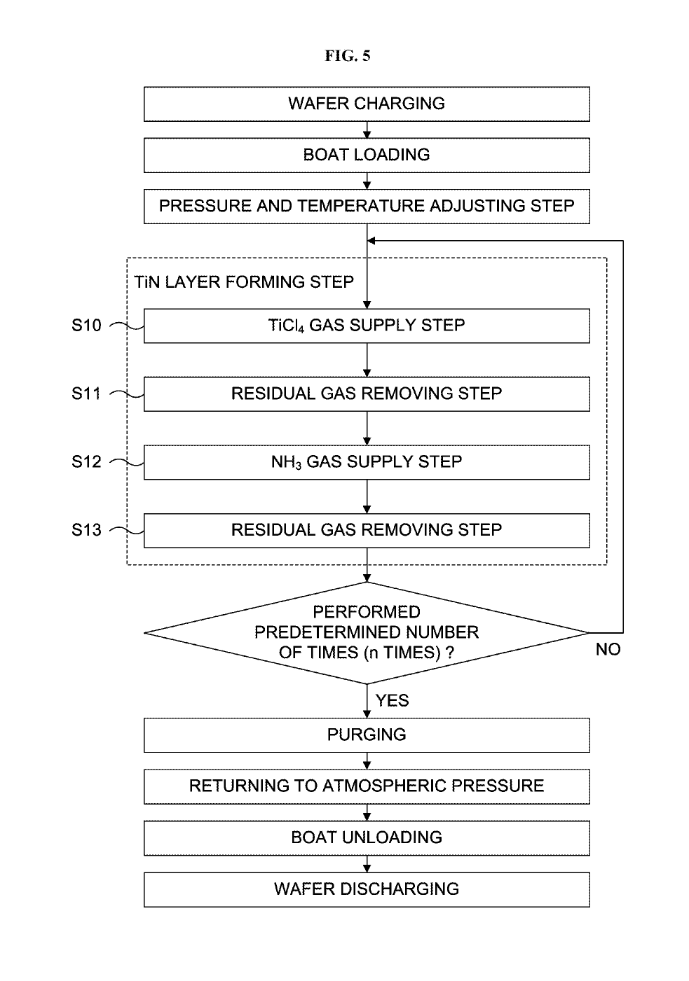

An exemplary sequence of forming a metal film on the wafer 200, which is one of substrate processings for manufacturing a semiconductor device, will be described with reference to FIG. 5. The sequence of forming the metal film is performed using the process furnace 202 of the substrate processing apparatus 10. In the description below, the components of the substrate processing apparatus 10 are controlled by the controller 121.

In the substrate processing (semiconductor manufacturing process) according to the first embodiment, a cycle is performed a predetermined number of times to form a titanium nitride layer (hereinafter, also referred to as a “TiN layer”) on the wafers 200. The cycle includes: (a) supplying TiCl₄ gas to the wafers 200 accommodated in the process chamber 201; (b) removing the TiCl₄ gas from the process chamber 201; (c) supplying NH₃ gas to the wafers 200; and (d) removing the NH₃ gas from the process chamber 201.

In the present specification, “wafer” may refer to “a wafer itself” or refer to “a wafer and a stacked structure (aggregated structure) of predetermined layers or films formed on the surface of the wafer”. That is, the wafer and the predetermined layers or films formed on the surface of the wafer may be collectively referred to as the wafer. In the present specification, “surface of wafer” refers to “a surface (exposed surface) of a wafer itself” or “the surface of a predetermined layer or film formed on the wafer, that is, the top surface of the wafer as a stacked structure”. In the present specification, “substrate” and “wafer” may be used as substantially the same meaning.

<Wafer Charging and Boat Loading Step>

After the boat 217 is charged with the wafers 200 (wafer charging), the boat 217 is elevated by the boat elevator 115 and loaded into the process chamber 201 (boat loading) as shown in FIG. 1. With the boat 217 loaded, the seal cap 219 seals the lower end opening of the reaction tube 203 via the O-ring 220b.

<Pressure and Temperature Adjusting Step>

The vacuum pump 246 vacuum-exhausts the process chamber 201 until the inner pressure of the process chamber 201 reaches a desired pressure (vacuum degree). In a pressure and temperature adjusting step, the inner pressure of the process chamber 201 is measured by the pressure sensor 245, and the APC valve 243 is feedback-controlled based on the measured pressure (pressure adjusting). The vacuum pump 246 continuously vacuum-exhausts the process chamber 201 until at least the processing of the wafers 200 is completed. The heater 207 heats the process chamber 201 such that the temperature of the wafers 200 in the process chamber 201 reaches a predetermined temperature. The energization state of the heater 207 is feedback-controlled based on the temperature detected by the temperature sensor 263 such that the inner temperature of the process chamber 201 has a desired temperature distribution (temperature adjusting). The heater 207 continuously heats the process chamber 201 until at least the processing of the wafers 200 is completed.

<TiN Layer Forming Step>

Next, a step of forming a first metal layer (for example, a metal nitride layer such as a TiN layer) is performed.

<TiCl₄ Gas Supply Step S10>

In a TiCl₄ gas supply step S10, the valve 314 is opened to supply TiCl₄ gas serving as the source gas, into the gas supply pipe 310. A flow rate of the TiCl₄ gas is adjusted by the MFC 312. The TiCl₄ gas with the flow rate thereof adjusted is supplied into the process chamber 201 through the gas supply holes 410a of the nozzle 410 to supply the TiCl₄ gas onto the wafers 200, and then exhausted through the exhaust pipe 231 Simultaneously, the valve 514 is opened to supply the inert gas such as N₂ gas into the gas supply pipe 510. A flow rate of the N₂ gas is adjusted by the MFC 512. The N₂ gas with the flow rate thereof adjusted is supplied with the TiCl₄ gas into the process chamber 201, and exhausted through the exhaust pipe 231. In order to prevent the TiCl₄ gas from entering the nozzle 420, the valve 524 is opened to supply the N₂ gas into the gas supply pipe 520. The N₂ gas is supplied into the process chamber 201 through the gas supply pipe 320 and the nozzle 420, and exhausted through the exhaust pipe 231.

In the TiCl₄ gas supply step S10, the APC valve 243 is appropriately controlled to adjust the inner pressure of the process chamber 201. For example, the inner pressure of the process chamber 201 may range from 0.1 Pa to 6,650 Pa. The flow rate of the TiCl₄ gas supplied into the process chamber 201 is adjusted by the MFC 312. For example, the flow rate of the TiCl₄ gas may range from 0.1 slm to 2 slm. The flow rates of the N₂ gas supplied into the process chamber 201 are adjusted by the MFCs 512 and 522, respectively. For example, the flow rates of the N₂ gas supplied into the process chamber 201 may range from 0.1 slm to 30 slm, respectively. The time duration of the supply of the TiCl₄ gas onto the wafers 200, for example, may range from 0.01 second to 20 seconds. In the TiCl₄ gas supply step S10, the temperature of the heater 207 is adjusted such that the temperature of the wafers 200 falls within a predetermined range from 250° C. to 550° C., for example.

In the TiCl₄ gas supply step S10, only the TiCl₄ gas and the N₂ gas are supplied into the process chamber 201. A titanium-containing layer having a thickness of, for example, less than one atomic layer to several atomic layers is formed on the wafers 200 (or on a underlying film on the wafers 200) by supplying the TiCl₄ gas.

<Residual Gas Removing Step S11>

After the titanium-containing layer is formed on the wafers 200, the valve 314 is closed to stop the supply of the TiCl₄ gas. With the APC valve 243 of the exhaust pipe 231 open, the vacuum pump 246 vacuum-exhausts the interior of the process chamber 201 to remove residual TiCl₄ gas which did not react or contributed to the formation of the titanium-containing layer from the process chamber 201. By maintaining the valves 514 and 524 open, the N₂ gas is continuously supplied into the process chamber 201. The N₂ gas acts as a purge gas, thus, it is possible to improve an effect of removing the residual TiCl₄ gas which did not react or contributed to the formation of the titanium-containing layer from the process chamber 201.

<NH₃ Gas Supply Step S12>

After the residual gas is removed from the process chamber 201, the valve 324 is opened to supply the NH₃ gas, which is a nitrogen (N)-containing gas serving as the reactive gas, into the gas supply pipe 320. A flow rate of the NH₃ gas is adjusted by the MFC 322. The NH₃ gas with the flow rate thereof adjusted is supplied into the process chamber 201 through the gas supply holes 420a of the nozzle 420 to be supplied onto the wafers 200, and then exhausted through the exhaust pipe 231. In a NH₃ gas supply step S12, the valve 524 is closed in order to prevent the N₂ gas from being supplied into the process chamber 201 together with the NH₃ gas. That is, the NH₃ gas is supplied into the process chamber 201 without being diluted with the N₂ gas, and is exhausted through the exhaust pipe 231. In order to prevent the NH₃ gas from entering the nozzle 410, the valve 514 is opened to supply the N₂ gas into the gas supply pipe 510. The N₂ gas is supplied into the process chamber 201 through the gas supply pipe 310 and the nozzle 410, and exhausted through the exhaust pipe 231. In the NH₃ gas supply step S12, the reactive gas (that is, the NH₃ gas) is supplied into the process chamber 201 without being diluted with the N₂ gas. Thus, it is possible to improve a film-forming rate of the TiN layer. It is also possible to adjust an atmosphere concentration of the N₂ gas in the vicinity of the wafers 200.

The APC valve 243 is appropriately controlled to adjust the inner pressure of the process chamber 201 when the NH₃ gas is supplied into the process chamber 201. For example, the inner pressure of the process chamber 201 may range from 0.1 Pa to 6,650 Pa. The flow rate of the NH₃ gas supplied into the process chamber 201 is adjusted by the MFC 322. For example, the flow rate of the NH₃ gas may range from 0.1 slm to 20 slm. The flow rate of the N₂ gas supplied into the process chamber 201 are adjusted by the MFC 512 such that the flow rate of the N₂ gas may range from 0.1 slm to 30 slm. A time duration of the supply of the NH₃ gas onto the wafers 200, for example, may range from 0.01 to 30 seconds. The temperature of the heater 207 is adjusted to be the same as that of the TiCl₄ gas supply step S10.

In the NH₃ gas supply step S12, only the NH₃ gas and the N₂ gas are supplied into the process chamber 201. A substitution reaction occurs between the NH₃ gas and at least a portion of the titanium-containing layer formed on the wafers 200 in the TiCl₄ gas supply step S10. During the substitution reaction, titanium contained in the titanium-containing layer and nitrogen contained in the NH₃ gas are bonded. As a result, the TiN layer containing titanium (Ti) and nitrogen (N) is formed on the wafers 200.

<Residual Gas Removing Step S13>

After the TiN layer is formed on the wafers 200, the valve 324 is closed to stop the supply of the NH₃ gas. The residual NH₃ gas which did not react or contributed to the formation of the TiN layer and reaction by-products are removed from the process chamber 201 according to the same process as the residual gas removing step S11.

<Performing a Predetermined Number of Times>

A TiN layer having a predetermined thickness (for example, from 0.1 nm to 2 nm) is formed on the wafers 200 by performing the cycle including the TiCl₄ gas supply step S10 through the residual gas removing step S13 performed in order a predetermined number of times (n times, n is a natural number equal to or greater than 1). Preferably, the cycle is performed a plurality of times. Preferably, for example, the cycle is performed 10 to 80 times, more preferably, 10 to 15 times.

<Purging and Returning to Atmospheric Pressure Step>

The N₂ gas is supplied into the process chamber 201 through each of the gas supply pipes 510 and 520, and then exhausted through the exhaust pipe 231. The N₂ gas acts as a purge gas. The process chamber 201 is thereby purged such that the residual gas or the reaction by-products remaining in the process chamber 201 are removed from the process chamber 201 (purging). Thereafter, the inner atmosphere of the process chamber 201 is replaced with the inert gas (replacing with inert gas), and the inner pressure of the process chamber 201 is returned to atmospheric pressure (returning to atmospheric pressure).

<Boat Unloading and Wafer Discharging Step>

Thereafter, the seal cap 219 is lowered by the boat elevator 115 and the lower end of the reaction tube 203 is opened. The boat 217 with the processed wafers 200 charged therein is unloaded from the reaction tube 203 through the lower end of the reaction tube 203 (boat unloading). Then, the processed wafers 200 are discharged from the boat 217 (wafer discharging).

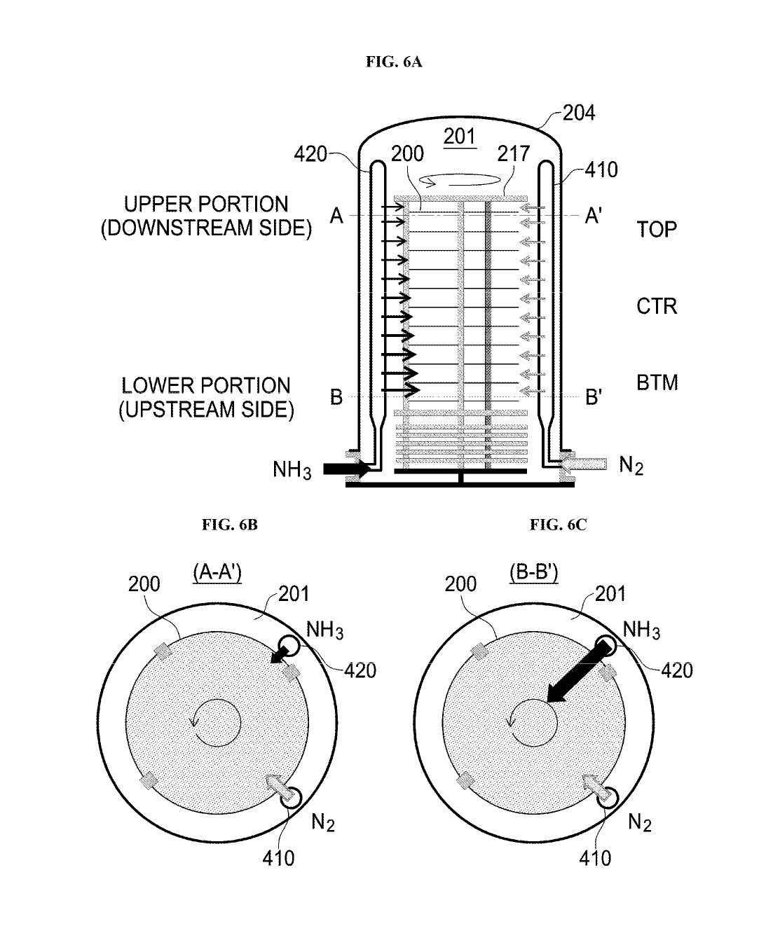

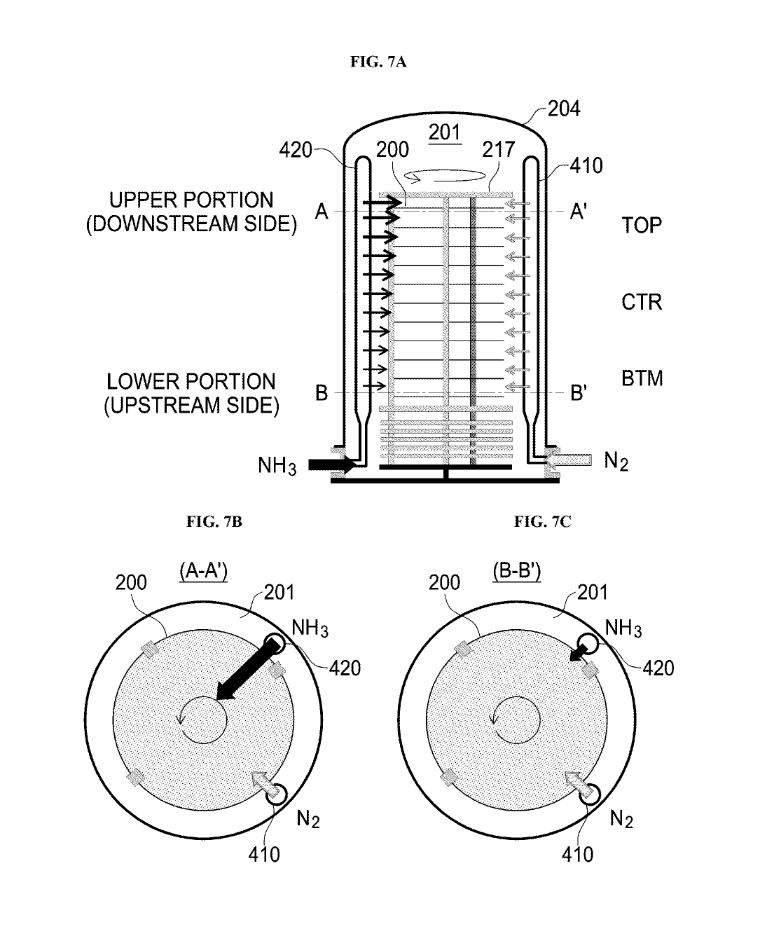

Next, the adjustment of the flow rate of the NH₃ gas supplied to the nozzle 420 in the step S12 described above and the effect thereof will be described in detail with reference to FIGS. 6A, 6B, 6C, 7A, 7B and 7C.

As shown in FIGS. 6A through 7C, the NH₃ gas is supplied into the process chamber 201 through the nozzle 420 and the N₂ gas is supplied into the process chamber 201 through the nozzle 410. The gas supply holes 420a of the nozzle 420 have the structure shown in FIG. 2. In FIGS. 6A through 7C, the flow directions of the gases (that is, the NH₃ gas and the N₂ gas) are indicated by the directions of the arrows, the partial pressures of the gases are indicated by the lengths of the arrows, and the flow rates of the gases are indicated by the thicknesses of the arrows, respectively. Other components of the substrate processing apparatus 10 are the same as those of the substrate processing apparatus 10 shown in FIG. 1, and descriptions thereof will be omitted.

FIG. 6A conceptually illustrates the flows of the gases in the process chamber 201 when the flow rate of the NH₃ gas to the nozzle 420 is relatively small. FIG. 6B conceptually illustrates the flows of the gases in a cross-section taken along the line A-A′ of FIG. 6A. FIG. 6C conceptually illustrates the flows of the gases in a cross-section taken along the line B-B′ of FIG. 6A.

According to the example shown in FIGS. 6A, 6B and 6C, the flow rate and the partial pressure of the NH₃ gas in the lower region of the nozzle 420 is greater than the flow rate and the partial pressure of the NH₃ gas in the upper region of the nozzle 420. That is, the supply amount of the NH₃ gas in the lower region is greater than that of the NH₃ gas in the upper region. Thus, it is possible to form a partial pressure balance in which the partial pressure of the NH₃ gas in the lower region is higher than that of the NH₃ gas in the upper region. Therefore, the thickness of the TiN layer formed on the wafers 200 located in the upper region can be made thin, and the thickness of the TiN layer formed on the wafers 200 located in the lower region can be made thick.

<Exemplary Conditions of Step S12 According to Example Shown in FIGS. 6A through 6C>

The inner temperature of the process chamber: 370° C. to 390° C.

The inner pressure of the process chamber: 50 Pa to 100 Pa

The flow rate of NH₃ gas: 5,000 sccm to 7,500 sccm

The time duration of NH₃ gas supply: 3 seconds to 30 seconds

FIG. 7A conceptually illustrates the flows of the gases in the process chamber 201 when the flow rate of the NH₃ gas to the nozzle 420 is relatively large. FIG. 7B conceptually illustrates the flows of the gases in a cross-section taken along the line A-A′ of FIG. 7A. FIG. 7C conceptually illustrates the flows of the gases in a cross-section taken along the line B-B′ of FIG. 7A.

According to the example shown in FIGS. 7A, 7B and 7C, the flow rate and the partial pressure of the NH₃ gas in the lower region of the nozzle 420 are less than the flow rate and the partial pressure of the NH₃ gas in the upper region of the nozzle 420. That is, the supply amount of the NH₃ gas in the upper region is greater than that of the NH₃ gas in the lower region. Thus, it is possible to form a partial pressure balance in which the partial pressure of the NH₃ gas in the upper region is higher than that of the NH₃ gas in the lower region. Therefore, the thickness of the TiN layer formed on the wafers 200 located in the lower region can be made thin, and the thickness of the TiN layer formed on the wafers 200 located in the upper region can be made thick.

<Exemplary Conditions of Step S12 According to Example Shown in FIGS. 7A through 7C>

The inner temperature of the process chamber: 370° C. to 390° C.

The inner pressure of the process chamber: 50 Pa to 100 Pa

The flow rate of NH₃ gas: 7,500 sccm to 10,000 sccm

The time duration of NH₃ gas supply: 3 seconds to 30 seconds

As is apparent from the examples shown in FIGS. 6A through 6C and FIG. 7A through 7C, it is possible to adjust the partial pressure balance of the process gas (that is, the NH₃ gas) supplied into the process chamber 201 through each of the gas supply holes 420a of the nozzle 420 shown in FIG. 2 to a desired state of the partial pressure balance by adjusting the flow rate of the process gas. Thus, it is possible to improve the uniformity of the thickness of the TiN layer between the wafers 200 stacked (accommodated) in the process chamber 201.

A first experimental example will be described below. However, the technique described herein is not limited to the first experimental example.

### FIRST EXPERIMENTAL EXAMPLE

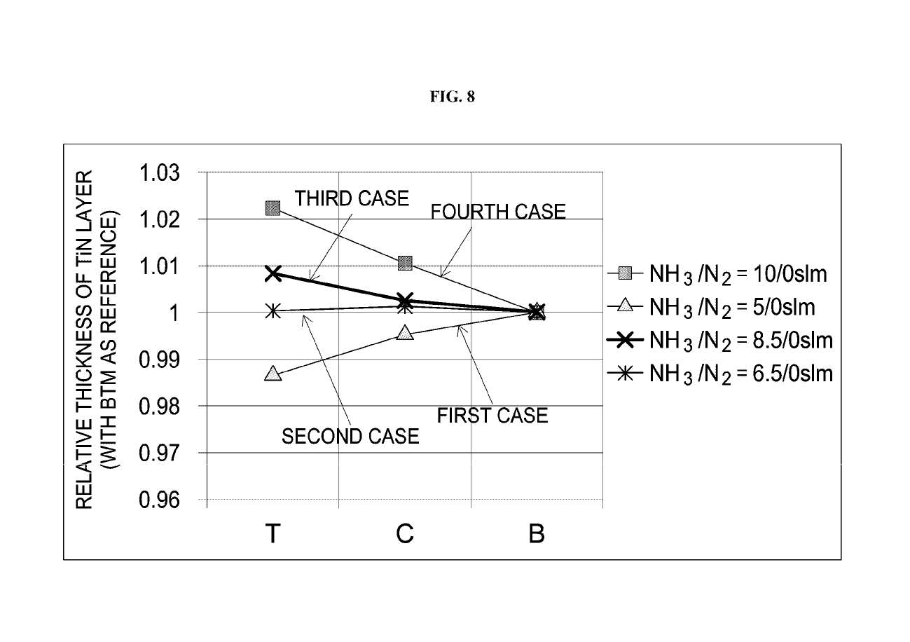

FIG. 8 illustrates a film-forming result obtained by changing the flow rate of the NH₃ gas serving as the reactive gas while the nozzle 420 shown in FIG. 2 is installed in the process chamber 201. The flow rate of the NH₃ gas supplied to the nozzle 420 is set under four conditions. That is, the flow rate of the NH₃ gas supplied to the nozzle 420 is 5.0 slm according to a first case, 6.5 slm according to a second case, 8.5 slm according to a third case, and 10.0 slm according to a fourth case. In addition, no N₂ gas is supplied to the nozzle 420, that is, the flow rate of the N₂ gas is 0.0 slm.

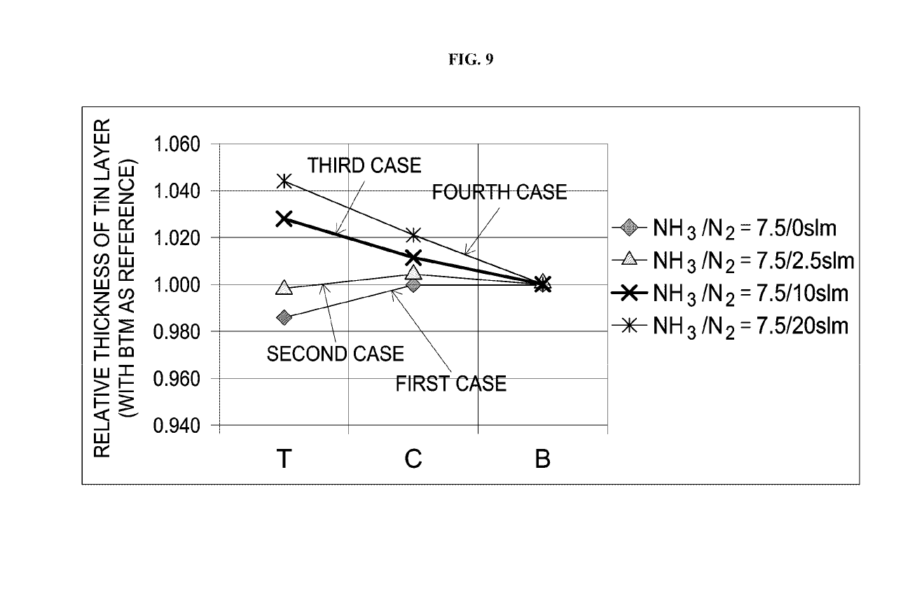

The film-forming result shown in FIG. 8 is obtained by inserting a monitor such as a monitor substrate for measuring the thickness of the TiN layer (also referred to as a “TiN film” in FIG. 8) into three regions of the process chamber 201 and monitoring the thickness of the TiN layer. As shown in FIGS. 6A and 7A, the three regions in the process chamber 201 are indicated by “TOP” (also indicated by “T” in FIGS. 8 and 9), “CTR” (also indicated by “C” in FIGS. 8 and 9) and “BTM” (also indicated by “B” in FIGS. 8 and 9) from the upper side to the lower side of the process chamber 201.

The horizontal axis of the graph shown in FIG. 8 represents the three regions indicated by “T”, “C” and “B” in the process chamber 201, and the vertical axis of the graph shown in FIG. 8 represents the relative thickness of the TiN layer formed on the wafers 200 corresponding to “TOP” (“T”) and “BTM” (“B”) regions, respectively, with reference to the thickness of the TiN layer formed on the wafer 200 corresponding to the “BTM” (“B”) region.

As is apparent from the film-forming result shown in FIG. 8, the thickness of the TiN layer of the respective regions (“T”, “C” and “B”) becomes substantially uniform when the flow rate of the NH₃ is about 6.5 slm, according to the second case. According to the first case where the flow rate of the NH₃ gas is less than that of the NH₃ gas according to the second case, the thickness of the TiN layer in the “TOP” (“T”) region is thinner than the thickness of the TiN layer in the “BTM” (“B”) region. According to the third case and the fourth case, where the flow rates of the NH₃ gas are greater than that of the NH₃ gas according to the second case, the thickness of the TiN layer in the “TOP” (“T”) region is thicker than the thickness of the TiN layer in the “BTM” (“B”) region. That is, by changing the flow rate of the NH₃ gas, it is possible to change or adjust the thickness balance of the TiN layer between the wafers 200 stacked (accommodated) in the process chamber 201. In the present specification, the thickness balance of the TiN layer between the wafers 200 are simply referred to as a “thickness balance between substrates” or “thickness balance between wafers”. Thus, it is also possible to adjust the thickness of the TiN layer in the “TOP” (“T”) region to be thinner than the thickness of the TiN layer in the “BTM” (“B”) region. On the contrary, it is also possible to form the thickness of the TiN layer in the “TOP” (“T”) region to be thicker than the thickness of the TiN layer in the “BTM” (“B”) region.

Conditions other than the flow rate of the NH₃ gas in the first experimental example are as follows.

<Conditions of First Experimental Example>

<Step 10>

The inner temperature of the process chamber: 370° C. to 390° C.

The inner pressure of the process chamber: 30 Pa to 50 Pa

The flow rate of TiCl₄ gas: 100 sccm to 200 sccm

The time duration of TiCl₄ gas supply: 3 seconds to 30 seconds

<Step S12>

The inner temperature of the process chamber: 370° C. to 390° C.

The inner pressure of the process chamber: 50 Pa to 100 Pa

The time duration of NH₃ gas supply: 3 seconds to 30 seconds

According to the first embodiment described above, the following one or more advantageous effects are provided.

1) It is possible to adjust the partial pressure balance of the reactive gas (NH₃ gas) in the process chamber 201 by adjusting the flow rate of the reactive gas (NH₃ gas) supplied into the process chamber 201 through the gas supply holes 420a of the nozzle 420 shown in FIG. 2. As above described, the opening area of each of the gas supply holes 420a in the nozzle 420 increases along a direction from the upstream side to the downstream side of the nozzle 420.

2) By adjusting the partial pressure balance of the reactive gas (NH₃ gas) in the process chamber 201, it is possible to adjust the thickness balance of the film (or layer) between the substrates stacked in the process chamber.

3) When the first embodiment is used for forming the TiN layer while adjusting the partial pressure balance of the reactive gas (NH₃ gas) in the process chamber 201, since the reactive gas (NH₃ gas) is supplied into the process chamber 201 without being diluted with the N₂ gas, it is possible to improve the film-forming rate of the TiN layer.

### First Modified Example of First Embodiment

According to the first embodiment described above, in the step S12, the NH₃ gas is supplied into the process chamber 201 through the nozzle 420 without being diluted with the N₂ gas, and the flow rate of the NH₃ gas supplied to the nozzle 420 is adjusted. However, according to a first modified example of the first embodiment, the NH₃ gas is diluted with the N₂ gas in the nozzle 420 and supplied into the process chamber 201. When the NH₃ gas supplied into the process chamber 201 according to the first modified example of the first embodiment, the flow rate of the NH₃ gas supplied to the nozzle 420 is fixed, and only the flow rate of the N₂ gas supplied to the nozzle 420 is changed.

### NH₃ Gas Supply Step S12 According to First Modified Example of First Embodiment

After the residual gas is removed from the process chamber 201, the valve 324 is opened to supply the NH₃ gas, which is the nitrogen (N)-containing gas serving as the reactive gas, into the gas supply pipe 320. The flow rate of the NH₃ gas is adjusted by the MFC 322. The NH₃ gas with the flow rate thereof adjusted is supplied into the process chamber 201 through the gas supply holes 420a of the nozzle 420 to be supplied onto the wafers 200, and then exhausted through the exhaust pipe 231. Simultaneously, the valve 524 is opened to supply the N₂ gas into the gas supply pipe 520. The flow rate of the N₂ gas is adjusted by the MFC 522. The N₂ gas whose flow rate is adjusted is supplied with the NH₃ gas into the process chamber 201, and exhausted through the exhaust pipe 231. In order to prevent the NH₃ gas from entering the nozzle 410, the valve 514 is opened to supply the N₂ gas into the gas supply pipe 510. The N₂ gas is supplied into the process chamber 201 through the gas supply pipe 310 and the nozzle 410, and exhausted through the exhaust pipe 231.

The APC valve 243 is appropriately controlled to adjust the inner pressure of the process chamber 201 when the NH₃ gas is supplied into the process chamber 201. For example, the inner pressure of the process chamber 201 may range from 0.1 Pa to 6,650 Pa. The flow rate of the NH₃ gas supplied into the process chamber 201 is adjusted by the MFC 322. For example, the flow rate of the NH₃ gas may range from 0.1 slm to 20 slm. The flow rates of the N₂ gas supplied into the process chamber 201 are adjusted by the MFCs 512 and 522, respectively, such that the flow rate of the N₂ gas adjusted by the MFC 512 and the flow rate of the N₂ gas adjusted by the MFC 522 may range from 0.1 slm to 30 slm, respectively. A time duration of the supply of the NH₃ gas onto the wafers 200, for example, may range from 0.01 to 30 seconds. The temperature of the heater 207 is adjusted to be the same as that of the TiCl₄ gas supply step S10 of the first embodiment.

### Exemplary Conditions of Step S12 According to First Modified Example of First Embodiment

The inner temperature of the process chamber: 370° C. to 390° C.

The inner pressure of the process chamber: 50 Pa to 100 Pa

The flow rate of NH₃ gas: 7,000 sccm to 8,000 sccm

The time duration of NH₃ gas supply: 3 seconds to 30 seconds

The flow rate of N₂ gas: 30 sccm to 30,000 sccm

A second experimental example will be described below. However, the technique described herein is not limited to the second experimental example.

### SECOND EXPERIMENTAL EXAMPLE

FIG. 9 illustrates another film-forming result obtained by fixing the flow rate of the reactive gas (NH₃ gas) supplied to the nozzle 420 and changing the flow rate of the N₂ gas supplied to the nozzle 420 while the nozzle 420 shown in FIG. 2 is installed in the process chamber 201.

The flow rate of the NH₃ gas supplied to the nozzle 420 is 7.5 slm, and the flow rate of the N₂ gas supplied to the nozzle 420 is set under four conditions. That is, the flow rate of the N₂ gas supplied to the nozzle 420 is 0.0 slm according to a first case, 2.5 slm according to a second case, 10.0 slm according to a third case, and 20.0 slm according to a fourth case.

Similar to FIG. 8, the film-forming result shown in FIG. 9 is obtained by inserting a monitor such as a monitor substrate for measuring the thickness of the TiN layer (also referred to as a “TiN film” in FIG. 9) into three regions of the process chamber 201 and monitoring the thickness of the TiN layer. As shown in FIGS. 6A and 7A, the three regions in the process chamber 201 are indicated by “TOP” (also indicated by “T”), “CTR” (also indicated by “C”) and “BTM” (also indicated by “B”) from the upper side to the lower side of the process chamber 201.

The horizontal axis of the graph shown in FIG. 9 represents the three regions indicated by “T”, “C” and “B” in the process chamber 201, and the vertical axis of the graph shown in FIG. 9 represents the relative thickness of the TiN layer formed on the wafers 200 corresponding to “TOP” (“T”) and “CTR” (“C”) regions with reference to the thickness of the TiN layer formed on the wafer 200 corresponding to the “BTM” (“B”) region.

As is apparent from the film-forming result shown in FIG. 9, the thickness of the TiN layer of the respective regions (“T”, “C” and “B”) becomes substantially uniform when the flow rate of the NH₃ is about 6.5 slm, according to the second case. According to the first case where the flow rate of the NH₃ gas is less than that of the NH₃ gas according to the second case, the thickness of the TiN layer in the “TOP” (“T”) region is thinner than the thickness of the TiN layer in the “BTM” (“B”) region. According to the third case and the fourth case, where the flow rates of the NH₃ gas are greater than t that of the NH₃ gas according to the second case, the thickness of the TiN layer in the “TOP” (“T”) region is thicker than the thickness of the TiN layer in the “BTM” (“B”) region. That is, by changing the flow rate of the NH₃ gas, it is possible to change or adjust the thickness balance of the TiN layer between the wafers 200 stacked (accommodated) in the process chamber 201. In the present specification, the thickness balance of the TiN layer between the wafers 200 are simply referred to as a “thickness balance between substrates” or “thickness balance between wafers”. Thus, it is also possible to adjust the thickness of the TiN layer in the “TOP” (“T”) region to be thinner than the thickness of the TiN layer in the “BTM” (“B”) region. On the contrary, it is also possible to form the thickness of the TiN layer in the “TOP” (“T”) region to be thicker than the thickness of the TiN layer in the “BTM” (“B”) region.

As described above, in the NH₃ Gas Supply Step S12 according to the first modified example of the first embodiment, the flow rate of the NH₃ gas supplied to the nozzle 420 is fixed or substantially constant, and only the flow rate of the N₂ gas supplied to the nozzle 420 is changed.

According to the first modified example of the first embodiment, it is possible to obtain the same advantageous effects as the above-described first embodiment.

### Second Modified Example of First Embodiment

According to the first modified example of the first embodiment described above, when the NH₃ gas is diluted with the N₂ gas in the nozzle 420 to simultaneously supply the NH₃ gas and the N₂ gas into the process chamber 201, the flow rate of the NH₃ gas supplied to the nozzle 420 is fixed, and only the flow rate of the N₂ gas supplied to the nozzle 420 is changed. However, according to a second modified example of the first embodiment, when the NH₃ gas is diluted with the N₂ gas in the nozzle 420 to simultaneously supply the NH₃ gas and the N₂ gas into the process chamber 201, both of the flow rate of the NH₃ gas and the flow rate of the N₂ gas supplied to the nozzle 420 are adjusted or changed.

It is possible to fine-tune the partial pressure balance of the reactive gas (NH₃ gas) in the process chamber 201 by changing both of the flow rate of the NH₃ gas and the flow rate of the N₂ gas.

### Second Embodiment

In a second embodiment, the flow rate of the NH₃ gas supplied to the nozzle 420 is fixed and the flow rate of the N₂ gas for preventing backflow supplied into the process chamber 201 through the nozzle 410 is adjusted or changed. In the second embodiment, when the NH₃ gas is supplied into the process chamber 201 through the nozzle 420 without being diluted with the N₂ gas as in the first embodiment, only the flow rate of the NH₃ gas supplied to the nozzle 420 is fixed. Further, in the second embodiment, when the NH₃ gas is diluted with the N₂ gas in the nozzle 420 and is simultaneously supplied to the process chamber 201 as in the first modified example of the first embodiment, both of the flow rate of the NH₃ gas supplied to the nozzle 420 and the flow rate of the N₂ gas supplied to the nozzle 420 for diluting the NH₃ gas are fixed. According to the second embodiment, the gas supply holes 410a of the nozzle 410 have the same configuration as the gas supply holes 420a of the nozzle 420 shown in FIG. 2.

### NH₃ Gas Supply Step S12 According to Second Embodiment

After the residual gas is removed from the process chamber 201, the valve 324 is opened to supply the NH₃ gas, which is the nitrogen (N)-containing gas serving as the reactive gas, into the gas supply pipe 320. The flow rate of the NH₃ gas is adjusted by the MFC 322. The NH₃ gas with the flow rate thereof adjusted is supplied into the process chamber 201 through the gas supply holes 420a of the nozzle 420 to be supplied onto the wafers 200, and then exhausted through the exhaust pipe 231.

Simultaneously, the valve 524 is opened to supply the N₂ gas into the gas supply pipe 520. The flow rate of the N₂ gas is adjusted by the MFC 522. The N₂ gas whose flow rate is adjusted is supplied with the NH₃ gas into the process chamber 201, and exhausted through the exhaust pipe 231. Alternatively, only the NH₃ gas is supplied into the process chamber 201 with the valve 524 closed.

In order to prevent the NH₃ gas from entering the nozzle 410, the valve 514 is opened to supply the N₂ gas into the gas supply pipe 510. The N₂ gas is supplied into the process chamber 201 through the gas supply pipe 310 and the nozzle 410, and exhausted through the exhaust pipe 231.

The APC valve 243 is appropriately controlled to adjust the inner pressure of the process chamber 201 when the NH₃ gas is supplied into the process chamber 201. For example, the inner pressure of the process chamber 201 may range from 0.1 Pa to 6,650 Pa. The flow rate of the NH₃ gas supplied into the process chamber 201 is adjusted by the MFC 322. For example, the flow rate of the NH₃ gas may range from 0.1 slm to 20 slm. The flow rate of the N₂ gas supplied into the process chamber 201 through the nozzle 410 and the flow rate of the N₂ gas supplied into the process chamber 201 through the nozzle 420 are adjusted by the MFCs 512 and 522, respectively, such that the flow rate of the N₂ gas supplied through the nozzle 410 and the flow rate of the N₂ gas supplied through the nozzle 420 may range from 0.1 slm to 30 slm, respectively. A time duration of the supply of the NH₃ gas onto the wafers 200, for example, may range from 0.01 to 30 seconds. The temperature of the heater 207 is adjusted to be the same as that of the TiCl₄ gas supply step S10 of the first embodiment.

According to the second embodiment, the flow rate of the NH₃ gas supplied to the nozzle 420 is fixed, and the flow rate of the N₂ gas for preventing backflow supplied into process chamber 201 through the nozzle 410 is adjusted. When the NH₃ gas is diluted with the N₂ gas in the nozzle 420 and is simultaneously supplied to the process chamber 201, both of the flow rate of the NH₃ gas supplied to the nozzle 420 and the flow rate of the N₂ gas supplied to the nozzle 420 for diluting the NH₃ gas are fixed.

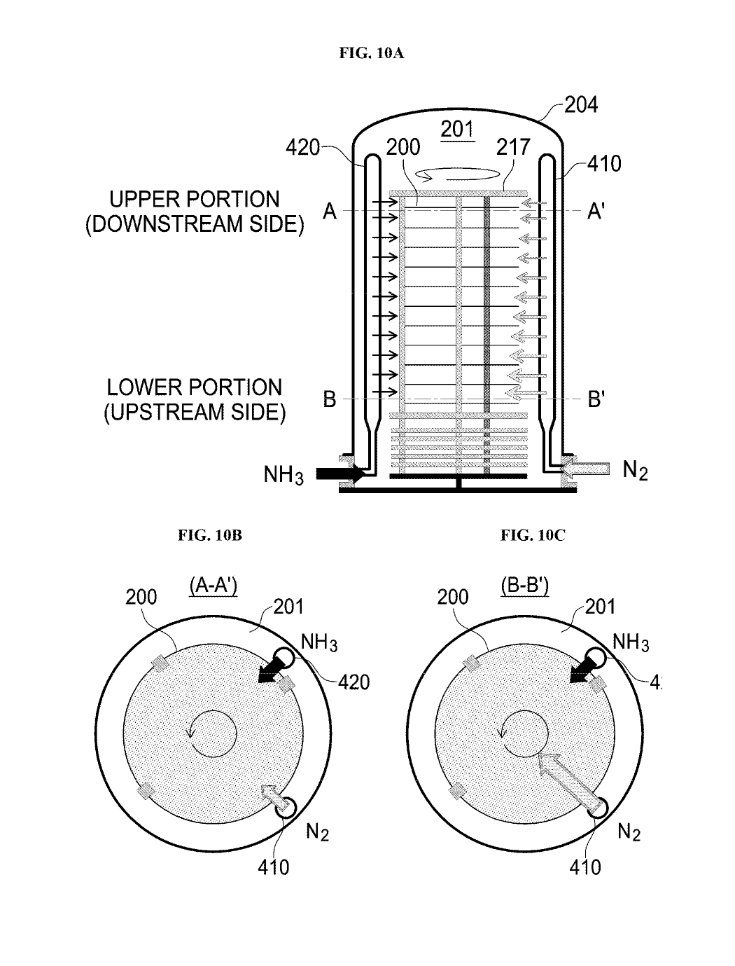

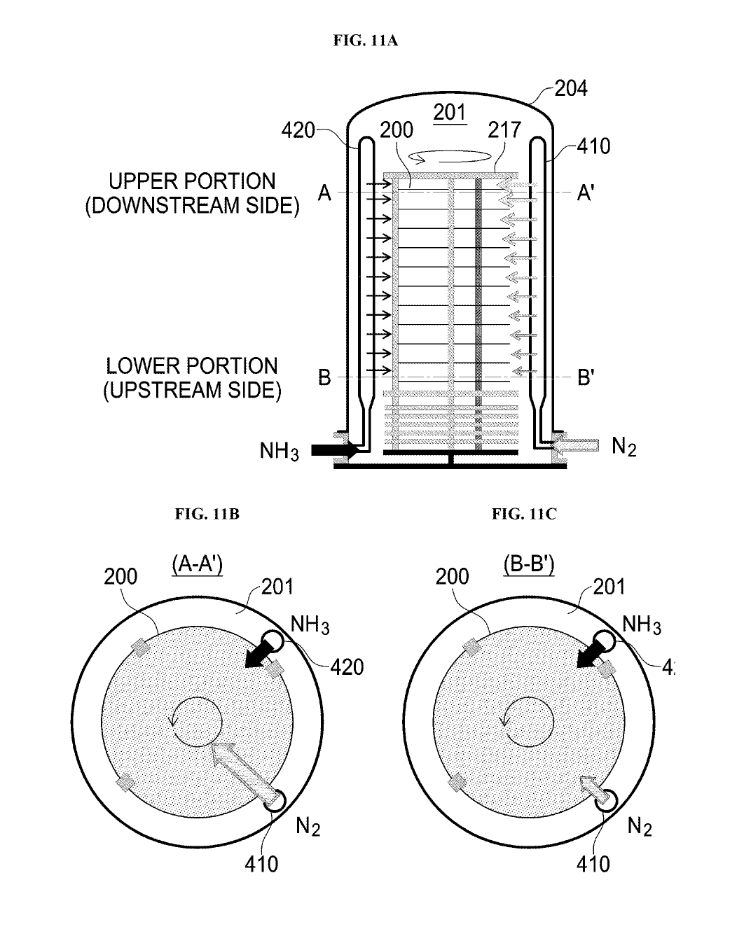

Next, the adjustment of the flow rate of the N₂ gas supplied to the nozzle 410 in the step S12 of the second embodiment described above and the effect thereof will be described in detail with reference to FIGS. 10A, 10B, 10C, 11A, 11B and 11C.

As shown in FIGS. 10A through 11C, the NH₃ gas is supplied into the process chamber 201 through the nozzle 420 and the N₂ gas is supplied into the process chamber 201 through the nozzle 410. The gas supply holes 410a of the nozzle 410 have the structure of the gas supply holes 420a shown in FIG. 2. In FIGS. 10A through 11C, the flow directions of the gases (that is, the NH₃ gas and the N₂ gas) are indicated by the directions of the arrows, the partial pressures of the gases are indicated by the lengths of the arrows, and the flow rates of the gases are indicated by the thicknesses of the arrows, respectively. Other components of the substrate processing apparatus 10 are the same as those of the substrate processing apparatus 10 shown in FIG. 1, and descriptions thereof will be omitted.

FIG. 10A conceptually illustrates the flows of the gases in the process chamber 201 when the flow rate of the N₂ gas to the nozzle 420 is relatively small. FIG. 10B conceptually illustrates the flows of the gases in a cross-section taken along the line A-A′ of FIG. 10A. FIG. 10C conceptually illustrates the flows of the gases in a cross-section taken along the line B-B′ of FIG. 10A.

According to the example shown in FIGS. 10A, 10B and 10C, the flow rate and the partial pressure of the N₂ gas in a lower region of the nozzle 410 is greater than the flow rate and the partial pressure of the N₂ gas in an upper region of the nozzle 410. That is, the supply amount of the NH₃ gas in the upper region is greater than that of the NH₃ gas in the lower region. Thus, it is possible to form a partial pressure balance in which the partial pressure of the NH₃ gas in the upper region is higher than that of the NH₃ gas in the lower region. Therefore, the thickness of the TiN layer formed on the wafers 200 located in the lower region can be made thin, and the thickness of the TiN layer formed on the wafers 200 located in the upper region can be made thick.

FIG. 11A conceptually illustrates the flows of the gases in the process chamber 201 when the flow rate of the N₂ gas to the nozzle 420 is relatively large. FIG. 11B conceptually illustrates the flows of the gases in a cross-section taken along the line A-A′ of FIG. 11A. FIG. 11C conceptually illustrates the flows of the gases in a cross-section taken along the line B-B′ of FIG. 11A.

According to the example shown in FIGS. 11A, 11B and 11C, the flow rate and the partial pressure of the N₂ gas in the lower region of the nozzle 410 are less than the flow rate and the partial pressure of the N₂ gas in the upper region of the nozzle 420. That is, the supply amount of the NH₃ gas in the lower region is greater than that of the NH₃ gas in the upper region. Thus, it is possible to form a partial pressure balance in which the partial pressure of the NH₃ gas in the lower region is higher than that of the NH₃ gas in the upper region. Therefore, the thickness of the TiN layer formed on the wafers 200 located in the upper region can be made thin, and the thickness of the TiN layer formed on the wafers 200 located in the lower region can be made thick.

As is apparent from the examples shown in FIGS. 10A through 10C and FIG. 11A through 11C, it is possible to adjust the partial pressure balance of the process gas in the process chamber 201 to a desired state of the partial pressure balance by fixing the flow rate of the process gas (that is, the NH₃ gas)supplied to the nozzle 420 (or maintaining the flow rate of the process gas supplied to the nozzle 420 as constant) and by adjusting the flow rate of the N₂ gas supplied to the nozzle 410 using the gas supply holes 410a of the nozzle 410 having the same configuration as the gas supply holes 420a of the nozzle 420 shown in FIG. 2. Thus, it is possible to improve the uniformity of the thickness of the TiN layer between the wafers 200 stacked (accommodated) in the process chamber 201. It is also possible to adjust the atmosphere concentration of the N₂ gas in the vicinity of the wafers 200.

According to the second embodiment, the following one or more advantageous effects are provided.

1) It is possible to easily achieve the partial pressure balance of the process gas (NH₃ gas) in the process chamber 201 where the partial pressure of the NH₃ gas in the lower region is higher than that of the NH₃ gas in the upper region.

2) Since the price of the N₂ gas is low, it is also possible to reduce the manufacturing cost of the TiN layer or the price of the semiconductor device (that is, the semiconductor chip) having the TiN layer.

3) When the flow rate of the NH₃ gas supplied to the nozzle 420 is changed, it affects the concentration of the NH₃ in the process chamber 201. However, the influence of the concentration of the NH₃ in the process chamber 201 is low in case of adjusting the flow rate of the N₂ gas for preventing backflow supplied into the process chamber 201 through the nozzle 410. Thus, it is possible to easily prepare the process recipe.

### Third Embodiment

A third embodiment is a combination of the first embodiment and the second embodiment.

That is, when the NH₃ gas is supplied into the process chamber 201 through the nozzle 420 in a NH₃ gas supply step S12 according to the third embodiment, the N₂ gas for preventing backflow is simultaneously supplied into the process chamber 201 through the nozzle 410. In the NH₃ gas supply step S12 according to the third embodiment, both of the flow rate of the NH₃ gas supplied to the nozzle 420 and the flow rate of the N₂ gas for preventing backflow supplied to the nozzle 410 are adjusted or changed. According to the third embodiment, the gas supply holes 410a of the nozzle 410 have the same configuration as the gas supply holes 420a of the nozzle 420 shown in FIG. 2.

According to the third embodiment, it is possible to fine-tune the partial pressure balance of the NH₃ gas in the process chamber 201 by adjusting both of the flow rate of the NH₃ gas supplied to the nozzle 420 and the flow rate of the N₂ gas for preventing backflow supplied to the nozzle 410. It is also possible to adjust the atmosphere concentration of the N₂ gas in the vicinity of the wafers 200.

### First Modified Example of Third Embodiment

According to a first modified example of the third embodiment, when the NH₃ gas is diluted with the N₂ gas in the nozzle 420 and supplied into the process chamber 201, the N₂ gas for preventing backflow is simultaneously supplied into the process chamber 201 through the nozzle 410 as in the first modified example of the first embodiment. However, according to the first modified example of the third embodiment, the flow rate of the NH₃ gas supplied to the nozzle 420 is fixed and both of the flow rate of the N₂ gas supplied to the nozzle 420 for diluting the NH₃ gas and the flow rate of the N₂ for preventing backflow gas supplied to the nozzle 410 are adjusted or changed. According to the first modified example of the third embodiment, the gas supply holes 410a of the nozzle 410 have the same configuration as the gas supply holes 420a of the nozzle 420 shown in FIG. 2.

According to the first modified example of the third embodiment, it is possible to fine-tune the partial pressure balance of the NH₃ gas in the process chamber 201 by adjusting both of the flow rate of the N₂ gas supplied to the nozzle 420 for diluting the NH₃ gas and the flow rate of the N₂ gas for preventing backflow supplied to the nozzle 410.

### Second Modified Example of Third Embodiment

According to a second modified example of the third embodiment, the flow rate of the NH₃ gas supplied to the nozzle 420, which is fixed in the first modified example of the third embodiment, is also adjusted or changed. That is, when the NH₃ gas is diluted with the N₂ gas in the nozzle 420 and supplied into the process chamber 201 and the N₂ gas for preventing back flow is simultaneously supplied into the process chamber 201 through the nozzle 410, the flow rate of the NH₃ gas supplied to the nozzle 420, the flow rate of the N₂ gas supplied to the nozzle 420 for diluting the NH₃ gas and the flow rate of the N₂ gas for preventing backflow supplied to the nozzle 410 are all adjusted or changed. According to the second modified example of the third embodiment, the gas supply holes 410a of the nozzle 410 have the same configuration as the gas supply holes 420a of the nozzle 420 shown in FIG. 2.

According to the second modified example of the third embodiment, it is possible to finely adjust the partial pressure balance of the NH₃ gas in the process chamber 201 by adjusting all of the flow rate of the NH₃ gas supplied to the nozzle 420, the flow rate of the N₂ gas supplied to the nozzle 420 for diluting the NH₃ gas and the flow rate of the N₂ gas for preventing backflow supplied to the nozzle 410.

### Other Embodiment

While the embodiments and the modified examples of the embodiments are described by way of the examples wherein the adjustment of the flow rate of the NH₃ gas, the flow rate of the N₂ gas for diluting the NH₃ gas and the flow rate of the N₂ gas for preventing backflow in the NH₃ gas supply step S12, the above-described technique is not limited thereto. The above-described technique may be applied to the adjustment of the flow rate of the TiCl₄ gas, the flow rate of the N₂ gas for diluting the TiCl₄ gas and the flow rate of the N₂ gas for preventing backflow in the TiCl₄ gas supply step S10.

While the embodiments and the modified examples of the embodiments are described in detail, the above-described technique is not limited thereto. For example, the above-described technique may also be applied to all types of films that can be formed using all kinds of gases by the vertical type film forming apparatus.

While the embodiments and the modified examples of the embodiments are described in detail, the above-described technique is not limited thereto. The above-described technique may be modified in various ways without departing from the gist thereof. For example, the above-described technique may also be applied when the embodiments and the modified examples of the embodiments are appropriately combined.

According to the technique described herein, it is possible to adjust a thickness balance of a film between substrates stacked in a process chamber of a substrate processing apparatus.

What is claimed is:

1. A method of manufacturing a semiconductor device, comprising
(a) supplying a source gas to substrates through a first nozzle vertically disposed along a stacking direction of the substrates in a process chamber where the substrates are stacked and accommodated; and
(b) supplying a reactive gas to the substrates through a second nozzle provided with opening portions and vertically disposed along the stacking direction of the substrates in the process chamber while adjusting a partial pressure balance of the reactive gas in the stacking direction of the substrates to a desired state, wherein an opening area of each of the opening portions increases along a direction from an upstream side to a downstream side of the second nozzle.

2. The method of claim 1, wherein an inert gas is simultaneously supplied with the reactive gas through the second nozzle in (b) while adjusting a flow rate of the inert gas supplied through the second nozzle according to the desired state.

3. The method of claim 1, wherein a flow rate of the reactive gas is adjusted in (b) according to the desired state.

4. The method of claim 1, wherein the first nozzle is provided with opening portions wherein an opening area of each of the opening portions of the first nozzle increases along a direction from an upstream side to a downstream side of the first nozzle, and
wherein, in (b), an inert gas is supplied through the first nozzle, the reactive gas and another inert gas is supplied through the second nozzle, and a flow rate of the inert gas supplied through the second nozzle is adjusted according to the desired state.

5. The method of claim 1, wherein the first nozzle is provided with opening portions wherein an opening area of each of the opening portions of the first nozzle increases along a direction from an upstream side to a downstream side of the first nozzle, and
wherein, in (b), an inert gas is supplied through the first nozzle, the reactive gas is supplied through the second nozzle, and a flow rate of the inert gas supplied through the first nozzle is adjusted according to the desired state.

6. The method of claim 1, wherein the first nozzle is provided with opening portions wherein an opening area of each of the opening portions of the first nozzle increases along a direction from an upstream side to a downstream side of the first nozzle, and
wherein an inert gas is simultaneously supplied through the first nozzle in (b) while the reactive gas is supplied through the second nozzle, and a flow rate of the inert gas supplied through the first nozzle and a flow rate of an inert gas supplied through the second nozzle are adjusted in (b), respectively, according to the desired state.

7. The method of claim 1, wherein the first nozzle is provided with opening portions wherein an opening area of each of the opening portions of the first nozzle increases along a direction from an upstream side to a downstream side of the first nozzle, and
wherein, in (b), an inert gas is supplied through the first nozzle, the reactive gas is supplied through the second nozzle, and a flow rate of the reactive gas is adjusted according to the desired state.

8. The method of claim 1, wherein the first nozzle is provided with opening portions wherein an opening area of each of the opening portions of the first nozzle increases along a direction from an upstream side to a downstream side of the first nozzle, and
wherein, in (b), an inert gas is supplied through the first nozzle, the reactive gas and another inert gas is supplied through the second nozzle, and a flow rate of the inert gas supplied through the first nozzle, a flow rate of the inert gas supplied through the second nozzle and a flow rate of the reactive gas are adjusted according to the desired state.

9. A non-transitory computer-readable recording medium storing a program causing a computer to control a substrate processing apparatus to perform:
(a) supplying a source gas to substrates through a first nozzle vertically disposed along a stacking direction of the substrates in a process chamber where the substrates are stacked and accommodated; and
(b) supplying a reactive gas to the substrates through a second nozzle provided with opening portions and vertically disposed along the stacking direction of the substrates in the process chamber while adjusting a partial pressure balance of the reactive gas in the stacking direction of the substrates to a desired state, wherein an opening area of each of the opening portions increases along a direction from an upstream side to a downstream side of the second nozzle.

10. The non-transitory computer-readable recording medium of claim 9, wherein an inert gas is simultaneously supplied with the reactive gas through the second nozzle in (b) while adjusting a flow rate of the inert gas supplied through the second nozzle according to the desired state.

11. The non-transitory computer-readable recording medium of claim 9, wherein a flow rate of the reactive gas is adjusted in (b) according to the desired state.

12. A substrate processing apparatus, comprising:
a process chamber where substrates are stacked and accommodated;
a gas supply system configured to supply a source gas and a reactive gas into the process chamber, the gas supply system comprising:
a first nozzle vertically disposed along a stacking direction of the substrates in the process chamber and configured to supply the source gas; and
a second nozzle vertically disposed along the stacking direction of the substrates in the process chamber and configured to supply the reactive gas, the second nozzle being provided with opening portions wherein an opening area of each of the opening portions increases along a direction from an upstream side to a downstream side of the second nozzle; and
a controller configured to control the gas supply system to perform:
(a) supplying the source gas to the substrates accommodated in the process chamber through the first nozzle; and
(b) supplying the reactive gas to the substrates through the second nozzle while adjusting a partial pressure balance of the reactive gas in the stacking direction of the substrates to a desired state.

13. The substrate processing apparatus of claim 12, wherein an inert gas is simultaneously supplied with the reactive gas through the second nozzle in (b) while adjusting a flow rate of the inert gas supplied through the second nozzle according to the desired state.

14. The substrate processing apparatus of claim 12, wherein a flow rate of the reactive gas is adjusted in (b) according to the desired state.
